(19) United States
(12) Patent Application Publication
(10) Pub. No.: US 2015/0050788 A1
(43) Pub. Date: Feb. 19, 2015

(54) Current steering element formation for memory arrays

(71) Applicant: Contour Semiconductor, Inc., North Billerica, MA (US)

(72) Inventor: Daniel Robert Shepard, North Hampton, NH (US)

(73) Assignee: Contour Semiconductor, Inc., North Billerica, MA (US)

(21) Appl. No.: 13/385,371

(22) Filed: Feb. 15, 2012

Related U.S. Application Data
(60) Provisional application No. 61/463,289, filed on Feb. 15, 2011.

(51) Int. Cl. H01L 45/00; H01L 21/265; H01L 21/306; H01L 27/24; H01L 29/66

(52) U.S. Cl. CPC H01L 45/16; H01L 27/2409; H01L 27/2436; H01L 29/66477; H01L 29/6609; H01L 21/306; H01L 21/26506; H01L 21/2654
USPC 438/238; 438/382

(57) ABSTRACT

The present invention is a method for forming a self-aligned, three dimensional structure in a crystalline surface and then converting that self-aligned, three dimensional structure into an array of diodes or current switches so as to minimize reverse leakage in the resulting array.

### CROSS-REFERENCE TO RELATED APPLICATIONS

This application claims priority to and the benefit of, and incorporates herein by reference in its entirety, U.S. Provisional Patent Application No. 61/463,289 by Shepard titled “ CURRENT STEERING ELEMENT FORMATION FOR MEMORY ARRAYS ” which was filed on Feb. 15, 2011. This application makes reference to U.S. Pat. No. 5,673,218 by Shepard which issued on Sep. 30, 1997 and is titled “DUAL-ADDRESSED RECTIFIER STORAGE DEVICE” and this patent is incorporated herein by reference in its entirety.

### TECHNICAL FIELD

In various embodiments, the present invention relates to storage elements as they relate to memory devices, and more particularly to storage elements comprising rectifiers or diodes made of crystalline materials such as silicon.

### BACKGROUND

In diode array solid state memory, memory cells comprise a current steering element such as a P-N junction diode. Such a memory array is described in U.S. Pat. No. 5,673,218 by Shepard. These diode memory cells are typically constructed between word lines in one direction and bit lines in the orthogonal direction where either the word lines or the bit lines are fabricated out of doped silicon. With the addition of resistive change or phase-change alloys as an information storage element (in series with the current steering element), one can create a reversibly switching, re-programmable memory cell.

In order to construct the current steering element upon the doped silicon bit or word line, silicon is often deposited in layers whereby the layers have different doping profiles in order to form the P-N junction of a diode. This deposited silicon is often deposited (by deposition techniques such as sputtering or CVD) or grown (such as by epitaxy) as amorphous silicon, poly-silicon or epi-silicon. However, when silicon is deposited upon a doped silicon base (such as a doped word or bit line), some of the dopant can diffuse out of the doped silicon base and into the deposited layer; this is referred to as auto-doping. This has the effect of lowering the doping concentration of the base (thereby increasing the resistivity of that base material) and increasing the doping concentration of the deposited layer (potentially to a concentration above what is desired). Furthermore, epitaxially deposited silicon often suffers from stacking faults whereby the grown crystalline silicon exhibits a mismatch to the silicon on which it is being grown and the border between the two sides of such mismatches can provide a path for electrons to pass, resulting in leakage currents through the resulting diodes. When the deposited silicon is deposited as either poly-silicon or amorphous silicon, these boundaries between the grains of deposited silicon can have similar pathe for the electrons to move but these paths are greater in number and cause greater leakage currents.

While it is possible to form diodes in the substrate material, the depths to which dopants must be implanted can result in damage to the crystalline structure that will also cause leakage paths. When a substrate is prepared with layers to form the vertically oriented diodes in advance, the precision required to etch that substrate in order to form the array of diodes can be difficult to control resulting in lower yields that render that approach non-manufacturable.

What is needed is a manufacturable method for forming diodes for use in a memory array that minimizes leakage currents while providing control over the structuring of the semiconducting junctions.

### SUMMARY

The present invention is a method for forming a self-aligned, three dimensional structure in a crystalline surface and then converting that self-aligned, three dimensional structure into an array of diodes or current switches so as to minimize reverse leakage in the resulting array.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, an embodiment of the present invention is described with reference to the following drawing, in which:

FIG. 1 is an exemplary drawing of a semiconductor memory cell in which a hole for forming a diode has been formed in accordance with an embodiment of the invention.

FIG. 2 is an exemplary drawing of a semiconductor memory cell in which a barrier layer for forming a diode has been formed in accordance with an embodiment of the invention.

FIG. 3 is an exemplary drawing of a semiconductor memory cell in which silicon has been grown for forming a diode in accordance with an embodiment of the invention.

FIG. 4 is an exemplary drawing of a semiconductor memory cell in which a diode has been formed in accordance with an embodiment of the invention.

### DETAILED DESCRIPTION

Memory cells according to the present invention can be fabricated using standard techniques and equipment. With the approach of the present invention, a current steering element such as a diode is fabricated with minimal process steps. The present invention will find applicability wherever an array of diodes or current switches is desired.

The present invention is a method to fabricate a self-aligned, three dimensional structure in a crystalline substrate, and then to convert this structure into an array of current steering devices (such as diodes) upon a plurality of parallel doped bit-lines. This is accomplished by forming the self-aligned silicon structure comprising long silicon stripes upon each of which is a plurality of pillars; this is followed by implanting between the pillars and utilizing an anneal to spread the implant underneath the pillar to form a connected bit-line and implanting the tops of the pillars with an opposite dopant to form current steering elements (e.g., diodes) out of the pillars.

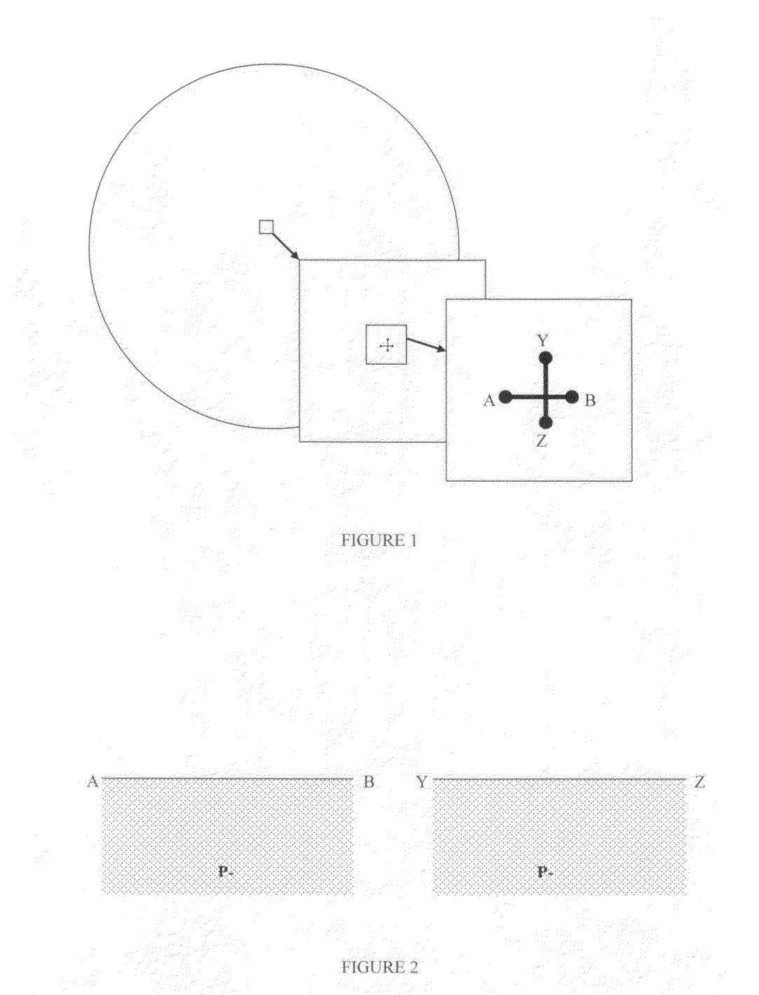

FIG. 1 depicts a silicon wafer with a zoomed in area indicating two places where cross-sections will be depicted in the subsequent drawings. The cross-sections are indicated by a first line labeled A-B and a second, orthogonal line labeled Y-Z.

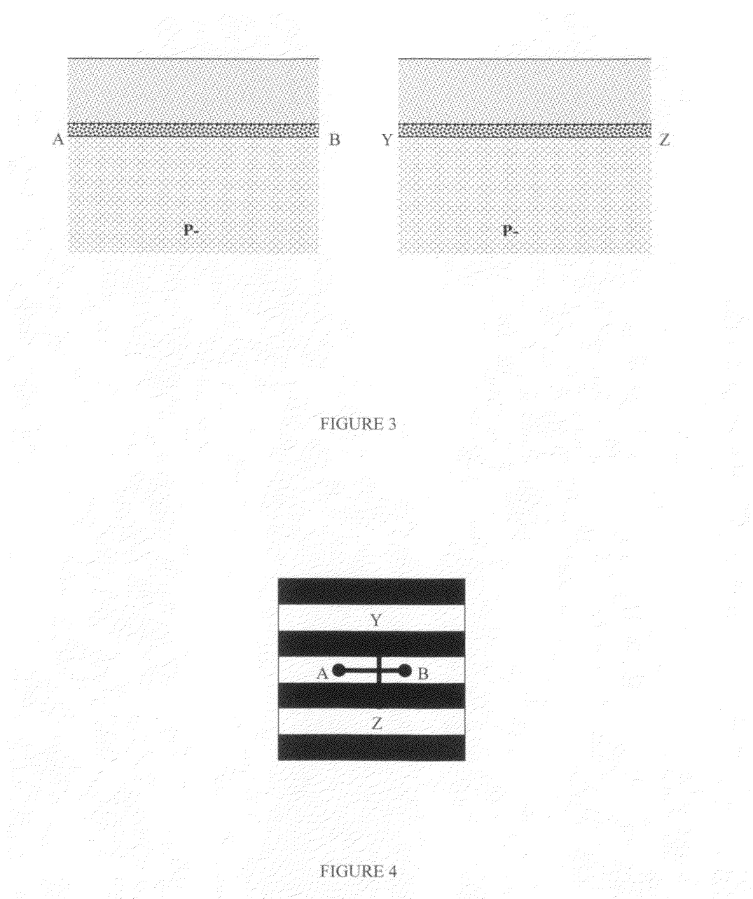

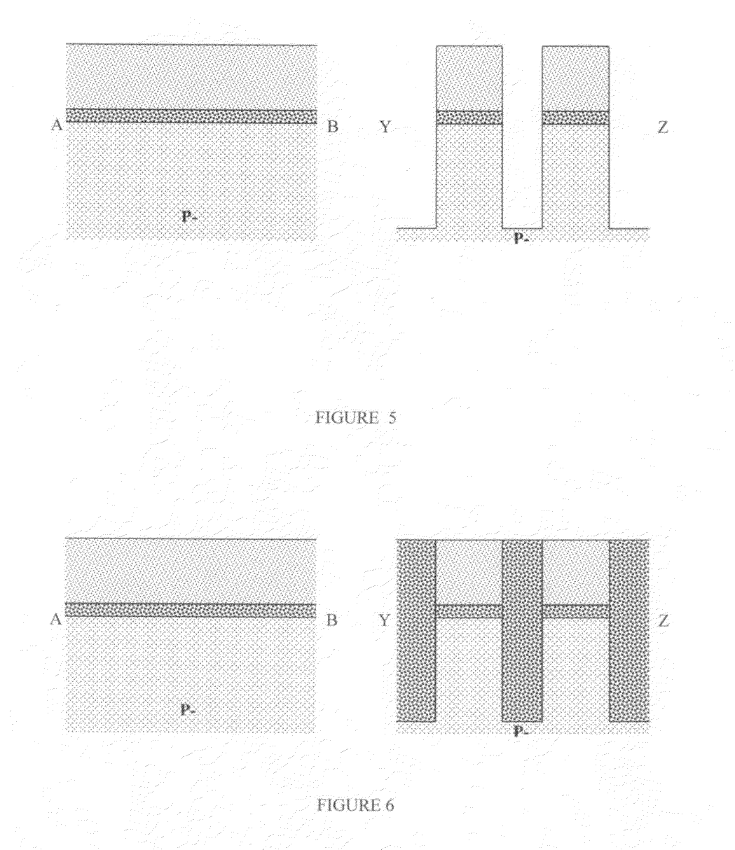

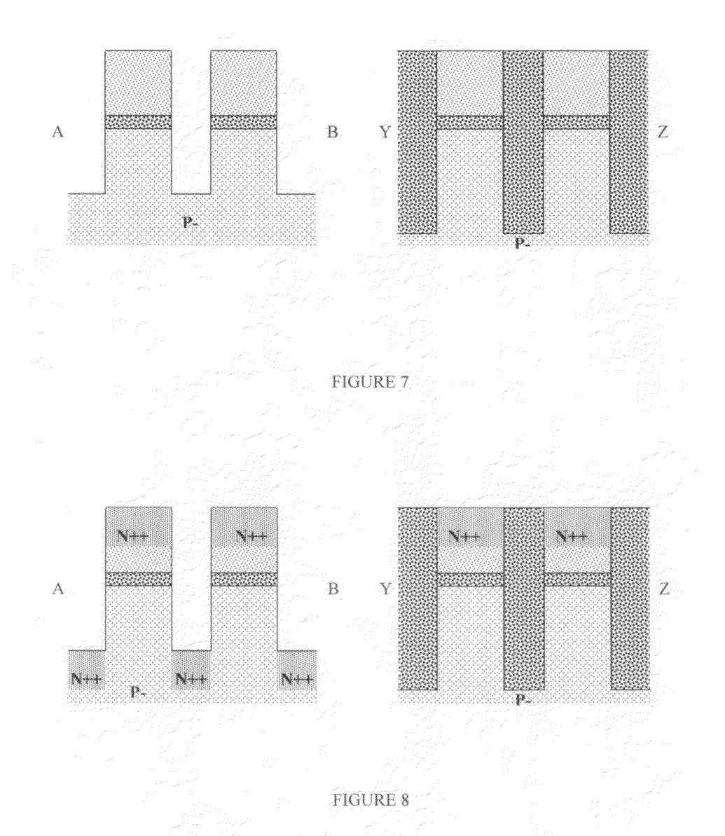

FIG. 2 depicts the cross-sections of A-B and Y-Z of the initial wafer. For purposes of discussion, this wafer is a standard wafer having a slight P-doping, but those skilled in the art will recognize that other starting wafer characteristics are possible in the context of the present invention.

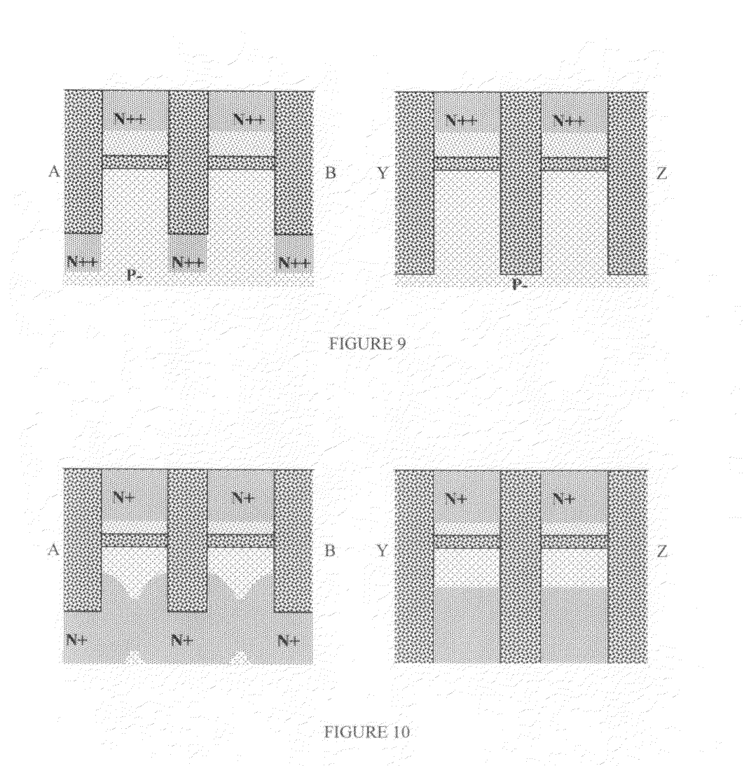

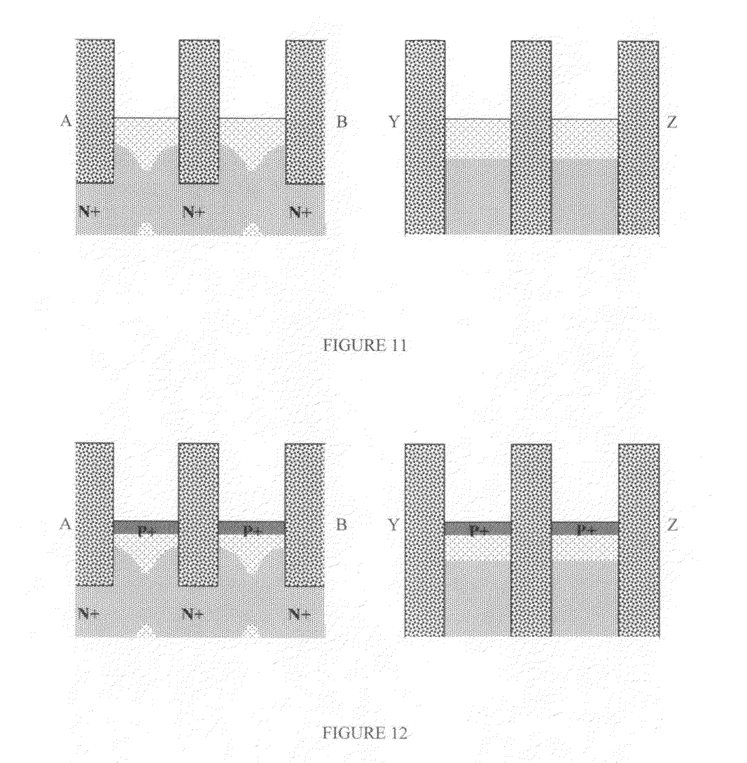

FIG. 3 depicts the cross-sections of A-B and Y-Z following a gate oxide growth and the deposition of poly-silicon both of which are formed using techniques well known by those skilled in the art. The poly-silicon will be used for the formation of MOS transistor gates as well as for a poly hard mask in the area of the diode array. Those skilled in the art will recognize that additional steps will be required both before and after these steps for the purpose of forming the MOS transistors, but these are well understood and not included in the present teaching for the purpose of clarity.

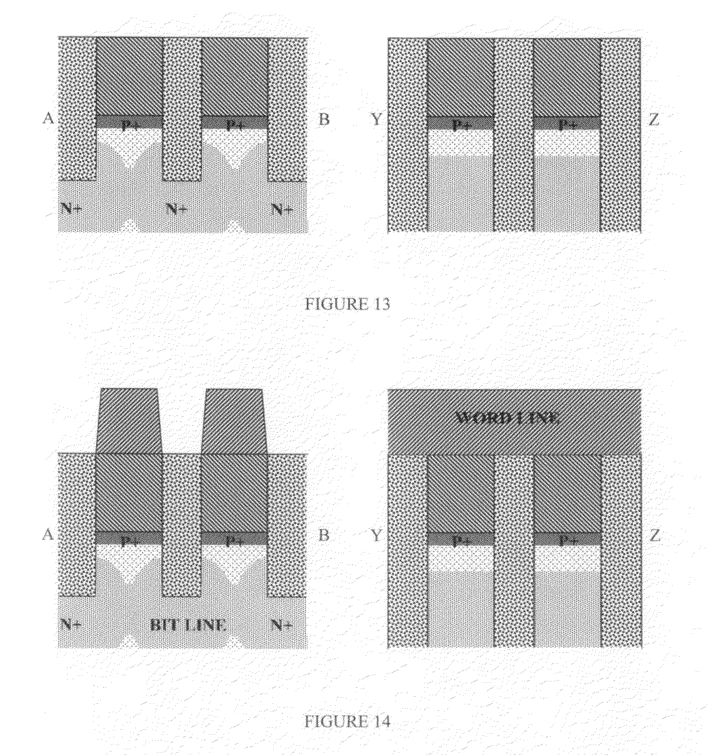

FIG. 4 depicts the patterning of shallow trench isolation features in top view showing the pattern of lines and spaces and FIG. 5 depicts the cross-sections of A-B and Y-Z following photo-patterning of the hard mask and etching of the STI trenches. FIG. 6 depicts the cross-sections following filling of the STI trenches; a thermal oxide is grown to passivate the sidewalls of the STI trenches followed by HDP oxide fill of the trenches and this is followed by oxide CMP planarization stopping on the poly silicon.

Next is the photo-patterning of the hard mask and etching of the diode separating trenches. This pattern of lines and spaces is applied orthogonally to the first pattern. FIG. 7 depicts the cross-sections of A-B and Y-Z following photo-patterning of the hard mask and etching of the STI trenches. This etch is made to be shallower than the first etch for the STI with the difference in depth corresponding to the height of the bit-lines that will be formed. Following this etch, the silicon sidewalls are passivated by a thermal oxide growth. This thermal oxide will also protect the silicon sidewalls during the following implant step. A slightly reentrant taper could also be used to protect the silicon sidewalls from the following implant as well (either in addition to the thermal oxide or in place of it).

The wafer is then implanted with a heavy dopant implant. This implant will heavily implant the silicon at the base of the diodes between the diodes, as is depicted in FIG. 8. The dose and depth is selected to yield the desired bit-line structure (depth and concentration) following a subsequent anneal.

FIG. 9 depicts the cross-sections following filling of the STI trenches; a thermal oxide is grown to passivate the sidewalls of the STI trenches followed by HDP oxide fill of the trenches and this is followed by oxide CMP planarization again stopping on the poly silicon.

FIG. 10 depicts the cross-sections of A-B and Y-Z following the bit-line spreading anneal. This anneal is performed to cause the dopant between the diodes to migrate under the diode and connect from either side of the diode to form the bit-line. This step can be omitted at this point in favor of an anneal that is performed after the P+ diode implant, or can be performed in addition to the P+ anneal. This gives flexibility in spreading the bit-line implant and forming the bit-line.

At this point, parallel processing of the MOS transistors can be performed. This will include patterning and forming the transistor gates and source and drain implants, gate sidewall spacers and source and drain contacts. After this, the second opportunity to perform an anneal is reached.

Following any transistor formation, the poly silicon hardmask is removed forming cups above the diodes as is depicted in FIG. 11. Into the cups is made a P+ implant to form the anode of the diodes as is depicted in FIG. 12 (if the initial bit-line material is N-type so as to form a P-I-N diode as is well known in the art). This P+ implant is then activated with a final anneal which could also be the anneal to spread the bit-line implants if an earlier anneal is not performed (or if the earlier anneal(s) was at a time and/or temperature that would start but not complete the bit-line formation).

The diode cups are then filled with whatever structure is desired. This can comprise a phase-change or other type of memory element to create a read/write memory element. Alternatively, this fill could comprise a tungsten plug (by tungsten deposition and CMP) to create a simple diode contact. This is depicted in FIG. 13. Whatever is employed as a cop filling mechanism, the diode array is then completed with a top metal interconnect of the word lines as depicted in FIG. 14.

The present invention is to create a self-aligned structure in silicon and then to convert that structure into rows of active elements (e.g., current steering elements such as diodes or current switches such as transistors) connected by bit-lines. Once the current steering element has been formed, an information storage element can be formed and the exposed top contact would then be electrically wired in with a metal contact through the application of traditional techniques for forming metal interconnects as is depicted in FIG. 14.

Embodiments of the present invention can be employed to form current steering elements whereby the semiconducting material comprises other materials than silicon, and these other materials include germanium and III-V semiconducting materials. Embodiments may be implemented with a traditional two dimensional arrangement of storage elements or with a three-dimensional arrangement of storage elements whereby each vertical stack or information storage elements will share the current steering element or current switching element below it. The storage elements could comprise a phase-change material (for PRAM) such as a chalcogenide alloy material (including a chalcogenide in which the programmed resistivity may be one of two resistance values and, in the case of more than one bit per cell storage cells, in which the programmed resistivity may be one of three or more resistance values) or a resistive change material (for RRAM), as well as a ferroelectric material (for FRAM), a magnetic or magnetoresistive material (for MRAM), magnetic tunnel junction or spin-transfer torque element (for MTJ-RAM or STT-RAM), a dual layer oxide memory element comprising a junction and an insulating metal oxide and a conductive metal oxide (see U.S. Pat. No. 6,753,561 by Rinerson), or a trapped charge device (see U.S. Pat. No. 7,362,609 by Harrison, et al). The phase-change material, such as a Chalcogenide material (e.g., GST or any of many alloy variants of GST), may be programmed or erased. The polarity of the voltages and direction of the currents in the storage bits may be reversed while still keeping within what is envisioned by embodiments of the present invention. The present invention may be applied to other memory technologies as well including static RAM, Flash memory, EEPROM, DRAM, ROM, OTP-ROM (by utilizing a fuse information storage element or an anti-fuse information storage element) and others not mentioned, including information storage element materials yet to be commercialized or invented.

Memory devices incorporating embodiments of the present invention may be applied to memory devices and systems for storing digital text, digital books, digital music (such as MP3 players and cellular telephones), digital audio, digital photographs (wherein one or more digital still images may be stored including sequences of digital images), digital video (such as personal entertainment devices), digital cartography (wherein one or more digital maps can be stored, such as GPS devices), and any other digital or digitized information as well as any combinations thereof. Devices incorporating embodiments of the present invention may be embedded or removable, and may be interchangeable among other devices that can access the data therein. Embodiments of the invention may be packaged in any variety of industry-standard form factor, including Compact Flash, Secure Digital, MultiMedia Cards, PCMCIA Cards, Memory Stick, any of a large variety of integrated circuit packages including Ball Grid Arrays, Dual In-Line Packages (DIPs), SOICs, PLCC, TQFPs and the like, as well as in proprietary form factors and custom designed packages. These packages may contain just the memory chip, multiple memory chips, one or more memory chips along with other logic devices or other storage devices such as PLDs, PLAs, micro-controllers, microprocessors, controller chips or chip-sets or other custom or standard circuitry.

The terms and expressions employed herein are used as terms and expressions of description and not of limitation, and there is no intention, in the use of such terms and expressions, of excluding any equivalents of the features shown and described or portions thereof. The present disclosure has been simplified at points for the sake of clarity, but these simplifications will be well understood by those skilled in the art. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A method of forming a memory array comprising the steps of:
a. patterning and etching to form a self-aligned, three dimensional structure in a crystalline surface and,
b. converting that self-aligned, three dimensional structure into an array of current controlling devices by implanting and annealing.

2. The method of claim 1 further comprising the formation of an information storage element.

3. The method of claim 2 whereby the information storage element material comprises a resistive change material.

4. The method of claim 2 whereby the information storage element material comprises a phase-change material.

5. The method of claim 4 whereby the phase-change material is a Chalcogenide alloy.

6. The method of claim 1 whereby the semiconducting material comprises silicon.

7. The method of claim 1 whereby the semiconducting material comprises germanium.

8. The method of claim 1 whereby the semiconducting material comprises a III-V semiconductor.

9. The method of claim 1 whereby the current controlling devices are diodes.

10. The method of claim 1 whereby the current controlling devices are transistors.
